(19) United States
(12) Patent Application Publication
(10) Pub. No.: US 2025/0176417 A1
(43) Pub. Date: May 29, 2025

(54) MULTIFUNCTIONAL OPTOELECTRONIC DEVICE

(71) Applicant: LinXole AB, Linköping (SE)

(72) Inventors: Feng GAO, Linköping (SE); Chunxiong BAO, Linköping (SE); Zhongcheng YUAN, Oxford (GB)

(21) Appl. No.: 18/727,025

(22) PCT Filed: Jan. 31, 2023
(86) PCT No.: PCT/SE2023/050081

§ 371 Date: Jul. 5, 2024

(30) Foreign Application Priority Data
Feb. 1, 2022 (SE) 2250096-1

(51) Int. Cl. H10K 65/00; C09K 11/06; H10K 30/40; H10K 50/135; H10K 85/10; H10K 85/50

(52) U.S. Cl. CPC H10K 65/00; C09K 11/06; H10K 85/111; H10K 85/151; H10K 85/50; C09K 2211/181; C09K 2211/188; H10K 30/40; H10K 50/135

(57) ABSTRACT

The present invention relates to a multifunctional optoelectronic device (10) comprising at least one photo-responsive perovskite light-emitting diode (LED, 1) arranged to alternatingly operate in emission mode and sensing mode. The at least one perovskite LED (1) comprises a cathode (2), an electron transport layer (ETL, 3) having a lowest unoccupied molecular orbital (LUMO) level and a highest occupied molecular orbital (HOMO) level, a perovskite layer (4) having a conduction band (CB) and a valence band (VB), a hole transport layer (HTL, 5) having a LUMO level and a HOMO level, and an anode (6). The LUMO level of the ETL (3) is lower than the CB bottom of the perovskite layer, and the HOMO level of the HTL (5) is higher than the VB top of the perovskite layer (4).

### TECHNICAL FIELD

The present invention relates to a multifunctional optoelectronic device, in particular a multifunctional display.

### BACKGROUND OF THE INVENTION

Display screen is usually a large-area indispensable component in modern electronics, such as smart phones, smart watches, laptop, tablet computers, etc. Conventionally, displays, including liquid crystal displays (LCD) and organic light-emitting diode (OLED) displays are designed to perform single function, i.e. information display. Thus, auxiliary functions, such as touch control, ambient light sensing, and fingerprint sensing, which are almost always essential in an electronic product, are normally achieved by the corresponding additional sensors, which inevitably increases the cost and makes the devices complex and cumbersome.

Using ultra-thin display screen with high screen-to-body ratio is currently one of the development trends of consumer electronics. Integrating the auxiliary functions provided by the additional sensors into the pixels of the display is an effective strategy to reduce thickness and increase screen-to-body ratio of the display. However, conventional display devices, e.g. LCD and OLED displays are incapable to effectively realize this application due to poor or absent sensing function in the pixels.

Metal halide perovskites have been recognized as promising emitters for high quality displays due to their high color purity, high efficiency, and compatibility with both solution-and vacuum deposition process. Moreover, combination of high photo-absorption, low exciton binding energy and outstanding carrier transport ability makes perovskites promising materials for photo-responsive LEDs. However, previously reported visible-light perovskite LEDs have demonstrated poor photoresponsivity.

Considering above, there is a need for an optoelectronic device, in particular a display, combining excellent light emission properties with high photoresponsivity thus allowing for integration of auxiliary functions in the device.

### SUMMARY OF THE INVENTION

The present invention thus discloses such a multifunctional device. In particular, the invention relates to a multifunctional display based on perovskite LED pixels, such as metal halide perovskite LED pixels. Benefiting from high photoresponsivity of the perovskites, the display is capable to include auxiliary functions, such as image sensor or touch screen, as will be described in greater detail below.

The main function of the multifunctional device of the present invention may be operation as a display, while the auxiliary functions may be touch sensor, fingerprint sensor, solar cell, or combinations thereof. It should be noted that both the main function and the auxiliary functions are provided by the perovskite LEDs. The multifunctional device of the present invention may further comprise other functions not provided by the perovskite LEDs.

The present invention thus discloses a multifunctional optoelectronic device comprising at least one photo-responsive perovskite light-emitting diode (LED) arranged to alternatingly operate in emission mode and sensing mode, wherein the at least one perovskite LED comprises a cathode, an electron transport layer (ETL) having a lowest unoccupied molecular orbital (LUMO) level and a highest occupied molecular orbital (HOMO) level, a perovskite layer having a conduction band (CB) and a valence band (VB), a hole transport layer (HTL) having a LUMO level and a HOMO level, and an anode, wherein the LUMO level of the ETL is lower than the CB bottom of the perovskite layer, and the HOMO level of the HTL is higher than the VB top of the perovskite layer.

The multifunctional device of the present invention may comprise a plurality of perovskite LEDs. By the term “plurality” is understood at least two.

Due to the fact that the LUMO level of ETL is lower than the CB bottom of perovskite and the HOMO level of the HTL is higher than the VB top of perovskite, there is no carrier separation barrier between charge transport layer and perovskite layer. The barrier would block the separation of photogenerated carrier and significantly reduce photoresponsivity of the device.

The at least one perovskite LED according to the present invention is arranged to exhibit light. The light emitted by the at least one perovskite LED is preferably in the visible spectrum, i.e. has a wavelength in the range from 380 nm to 750 nm. Further, the at least one perovskite LED of the present invention can be arranged to function as a photodetector.

The multifunctional device of the present invention further comprises a sensing circuit comprising a sensor arranged to determine the electric current through the at least one perovskite LED and a switch arranged to select between the emission mode and the sensing mode of the perovskite LED as a function of the electric current through the at least one perovskite LED. The sensor may be a current sensor or a voltage sensor.

Put differently, the sensing circuit is arranged to read out the current for each perovskite LED, or pixel, and control bias in the circuit. The sensing circuit can be designed in the substrate or may be an external driving circuit of the display.

The multifunctional device according to the present invention offers a number of advantages. First, the pixels in multifunctional perovskite display can work in both emitting and sensing mode. Second, a sensing circuit is designed to read the photocurrent of the pixels, particularly when they are in sensor mode. From this data, the multifunctional display can sense the touch position, image (act as fingerprint sensor or scanner) or information from optical communication. Moreover, the pixels can be used as solar cells to convert light energy into electricity to charge the devices.

As mentioned above, for perovskite LEDs, in order to obtain decent performance, charge confinement structures are always introduced to restrict the charge carrier recombination in the perovskite layer. However, photo-response of these devices is always strongly limited due to the photo-generated carriers being confined in the perovskite layer rather than separated and collected by the electrodes. To achieve good sensing performance, devices having low energy barriers between the charge transport layer and perovskite layer are desired. However, in such devices, the ratio of nonradiative recombination of carrier would increase and the light emitting efficiency would be decreased. Reducing the nonradiative recombination centres is specifically significant for these devices to gain both good light emitting and sensing performance. To this end, the perovskite layer of the multifunctional device may comprise a passivation agent. The passivation agent may be 2,2′-(ethylenedioxy)diethylamine (EDEA), 2,2′-(oxybis(ethylenoxy))diethylamine (ODEA), 5-aminovaleric acid (5-AVA), 5-aminovaleric acid hydroiodide (5-AVAI), or 5-aminovaleric acid hydrobromide (5-AVABr). Addition of the passivation agents significantly reduces the nonradiative recombination centres, thus leading to a perovskite layer having high photoluminescence quantum efficiency (PLQE). In particular, PLQE may be above 40%.

According to the present invention, the perovskite layer may comprise a metal halide perovskite. The metal halide perovskite may be a metal halide perovskite having a general formula AM^{II}X₃, a double perovskite having general formula A₂M^{I}M^{III}X₆, a layered perovskite having general formula A′AₙMₙX₃ₙ₊₁ or combination thereof.

In the general formulas above A is a small monovalent cation, A′ is a large monovalent cation, M^{I} is a monovalent metal cation, M^{II} is a divalent metal cation, M^{III} is a trivalent metal cation, and X is an anion.

The small monovalent cation may be selected from a group consisting of methylammonium (MA⁺), formamidinium (FA⁺), Cs⁺ and combination thereof.

The large monovalent cation may be an aliphatic or aromatic alkylammonium. In particular, the large monovalent cation may be selected from a group consisting of n-butylammonium (n-BA⁺), 2-phenylethylammonium (PEA⁺), 1-naphthylmethylammonium (NMA⁺) and combinations thereof.

The monovalent metal cation may be but is not limited to Ag⁺. Alternatively, or additionally, the divalent metal cation may be selected from a group consisting of Pb²⁺, Sn²⁺, Ga²⁺, Ge²⁺ and combinations thereof. Further, the trivalent metal cation may be selected from a group consisting of Bi³⁺, In³⁺, Sb³⁺ and combinations thereof.

The anion may be a halide anion. In particular, the anion may be a mixture of bromide (Br⁻), iodide (I⁻) and chloride (Cl⁻).

According to a particular embodiment, the metal halide perovskite is APbI₂Br, where A is Cs⁺, FA⁺ or their combination. The proper ratio of I:Br makes the emission peak locate around 650 nm, which promises a saturated red color and a good luminance efficiency. Devices based on the co-passivated APbI₂Br perovskite with low energy barrier can simultaneously achieve high light emitting and sensing efficiency.

The multifunctional device according to the present invention offers one more signal input or sense method based on the hardware in addition to the traditional display. It opens up many new application possibilities which can be enabled through the program design. Some examples include the functions of touch interface, fingerprint reading and ambient detecting without additional devices or sensors. This helps achieving an ultra-thin screen with high screen-to-body ratio. Moreover, some new functions can be developed using the display, such as solar cell for charging the device and data communications through the screen.

The multifunctional device according to the present invention may comprise a driving circuit. In such an embodiment, the sensing circuit may be integrated into the driving circuit.

The thickness of the ETL and/or the HTL may be from 20 nm to 100 nm. Further, the thickness of the perovskite layer may be from 50 nm to 500 nm. Indeed, the thickness of the layers of the perovskite LED may be varied in order to achieve desired performance.

The ETL may be polyethylenimine ethoxylated (PEIE) modified or pure zinc oxide (ZnO), tin oxide (SnO₂) or titanium oxide (TiO₂). The multifunctional device according to any one of the preceding clams, wherein the HTL is poly (9,9-dioctylfluorene-co-N-(4-sec-butylphenyl)-diphenylamine) (TFB)/molybdenum oxide (MoOₓ).

As mentioned above, the multifunctional device according to the present invention may be a display comprising auxiliary functions provided by the perovskite LEDs. It is desired that the screen-to-body ratio of the multifunctional display is maximized. In particular, the multifunctional device may have a screen-to-body ratio of at least 90%.

As is evident from above, photoresponsivity of perovskite LEDs emitting in visible region is significantly enhanced while keeping the outstanding light-emitting performance through sufficient defects passivation. Excellent performance in both light-emitting and light-response of these pixels makes them a promising candidate for successful fabrication of multifunctional displays comprising integrated auxiliary functions such as touch screen, ambient light sensor and fingerprint sensors, thus providing an ultra-thin display with significantly reduced cost. Further, a charging function may be integrated in the display, wherein a battery may be charged using the display to convert the energy of ambient light into electricity. Another application is a device-to-device communication function using the display as signal transmitter and receiver. Finally, a heart pulse rate and oximeter sensor using the display pixels as light source and detector may be provided.

### BRIEF DESCRIPTION OF THE DRAWINGS

Embodiments of the invention will now be described by way of example with reference to the accompanying drawings, of which:

FIG. 1 is a schematic illustration of photo-responsive perovskite LED;

FIG. 2a is a cross-sectional view of perovskite LED;

FIG. 2b depicts an energy diagram of the photo-responsive perovskite LED;

FIG. 3 shows a schematic structure of the driving/sensing circuit in the multifunctional perovskite display;

FIG. 4 illustrates a multifunctional perovskite display according to the present invention;

FIG. 5 illustrates J-V and luminance-voltage curves of perovskite LED;

FIG. 6 depicts an EQE and energy conversion efficiency of perovskite LED;

FIG. 7a depicts a J-V curve of the perovskite device working as solar cell under AM1.5 solar simulator;

FIG. 7b illustrates a J-V curve of the perovskite device working as solar cell under illumination from a white LED lamp (4000 K, 1000 lux);

FIG. 8 depicts a specific detectivity spectrum of the perovskite device working as photodetector test under zero bias;

FIG. 9a illustrates a transient photocurrent (TPC) curves of perovskite devices with different areas working as photodetector;

FIG. 9b illustrates response times obtained by fitting the TPC curves for different area devices;

FIG. 10 illustrates a schematic structure of perovskite LED display;

FIG. 11a shows the touch position sensing of the perovskite LED display;

FIGS. 11b-d shows the images of inputting information by touching the perovskite LED display;

FIG. 12a shows the image sensor function of the perovskite display;

FIG. 12b depicts an image obtained by the perovskite display when working as image sensor;

FIG. 13 illustrates PPG results of the commercial PPG sensor comprised with a green III-V LED bead and a Si photodiode and perovskite display;

FIG. 14a illustrates a charging curve of a supercapacitor using the perovskite LED as power source;

FIG. 14b depicts a discharging curve of a supercapacitor using the perovskite LED as power load;

### DETAILED DESCRIPTION OF THE INVENTION

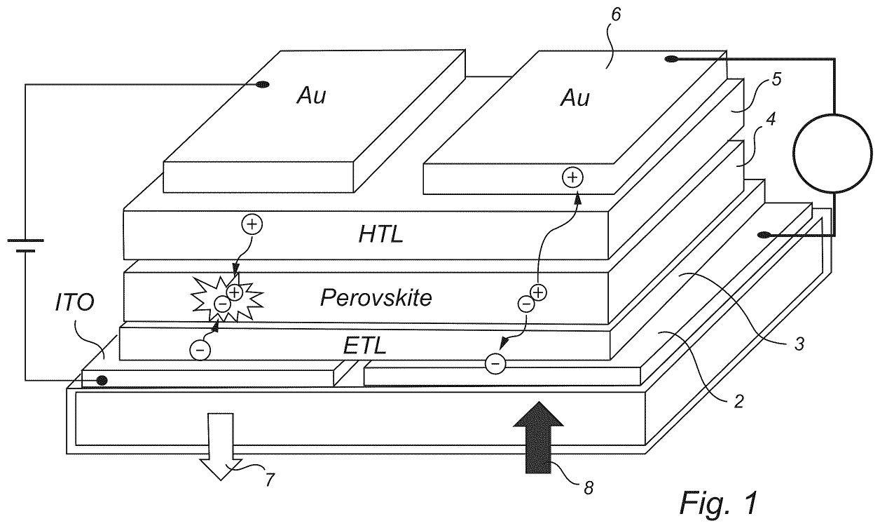

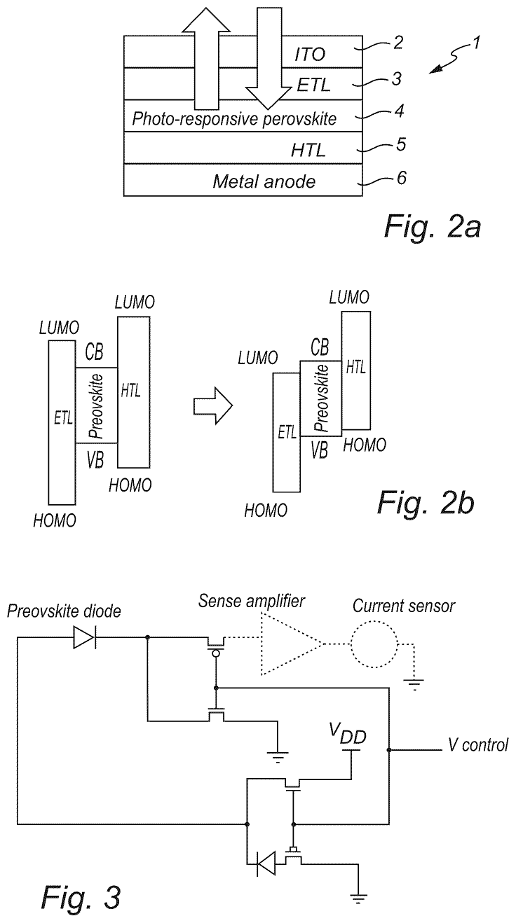

The perovskite LED 1 according to the present invention was prepared as follows. Pre-patterned indium tin oxide (ITO) substrates 2 were cleaned with detergent and rinsed with deionized water, followed by a 15 minutes UV-ozone treatment after drying the substrates with air flow. Zinc oxide (ZnO) suspension in ethanol was synthesized and prepared according to a procedure known in the art. The ZnO layer 3 was prepared by spin-coating the ZnO suspension on the cleaned ITO substrates 2 at 4000 rpm before transferring to a nitrogen-filled glovebox. Perovskite precursor solution was prepared by mixing PbI₂ (0.125 M), CsBr (0.25 M), FAI (0.25 M) in DMF and stirred at 60° C. for 1 hour. Different amounts of 5AVAI (0˜0.038 M) are further introduced as processing additives. The perovskite precursor solutions were coated on top of ZnO layers at 4000 rpm for 30 s and then annealed on a hot plate at 120° C. for 10 minutes, thus forming perovskite layer 4. After cooling down, a TFB layer 5 (12 mg/mL in chlorobenzene) was further coated as HTL. The devices were finished by evaporating MoOₓ (7 nm) and Au (50 nm) as electrodes 6 in a thermal evaporator under a chamber pressure of 2×10⁻⁶ Pa. The LED and PV device pixels had sizes of 7.25 mm², which were defined by a shadow mask. The perspective and cross-sectional view of the perovskite LED 1 is shown in FIGS. 1 and 2a, respectively. LED mode of the perovskite LED is shown by the white arrow 7, while the photodetection/solar cell mode is shown by the black arrow 8.

To make sure the photogenerated carrier can be effectively separated and collected, ZnO and TFB were as the electron and hole transport layers 3, 5, respectively, both of which have demonstrated as efficient charge transport layers in high performance perovskite solar cells. Here, three-dimensional (3D) mixed halide FA_{y}Cs_{1-y}PbI₃₋ₓBrₓ perovskite films are used as photoactive layers and light-emitting layers. When the devices are working in a PV model, the photogenerated carriers in FA_{y}Cs_{1-y}PbI₃₋ₓBrₓ perovskite films can be efficiently collected by the anodes and cathodes to output circuit. While at LED mode, the injected electrons and holes from the external circuit recombine in the perovskite layer and emit light.

As mentioned above, the LUMO level of the ETL 3 is lower than the CB bottom of the perovskite layer 4, and the HOMO level of the HTL 5 is higher than the VB top of the perovskite layer 4, as shown in FIG. 2b, right, and as compared with energy diagram of a conventional device, illustrated in the left portion of FIG. 2a.

The dashed line depicted in FIG. 3 illustrates the sensing unit and control bias in the circuit. Voltage control selects between the LED mode and the sensing mode of the perovskite LED. When the value of the voltage control is high, LED mode is ON, while when the value of the voltage control is low, sensor mode ON.

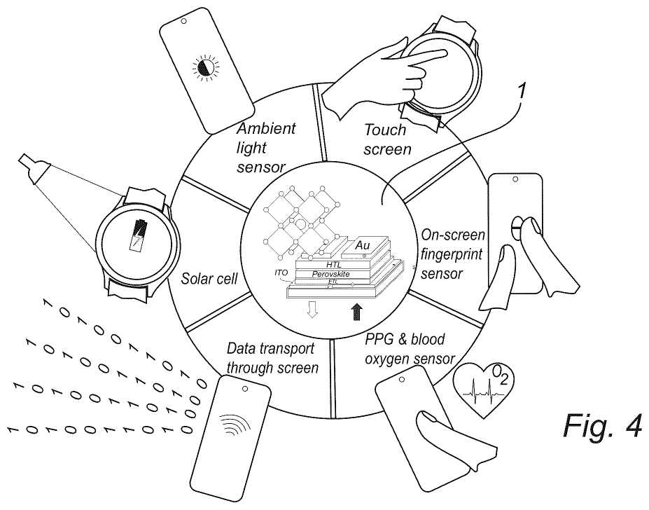

In FIG. 4, some functions realized by the multifunctional display of the present invention are presented. As may be seen, the multifunctional display may incorporate a number of auxiliary functions, such as an ambient light sensor, solar cell, touch screen, data transport, photoplethysmography (PPG) and oximeter.

The devices according to the present invention were studied as follows. The J-V curves, EQE and luminance of the perovskite LEDs were measured on a LED testing platform, where a spectrometer (QE Pro, Ocean Optics) coupled with an integrating sphere (FOIS-1) and a source meter (Keithley 2400) were used to measure device emission and electric data at different scanning voltages in a glovebox. The solar cell performance was measured using the source meter (Keithley 2400) under an AM1.5 sunlight simulator or a commercial LED lamp. The photo-to-current conversion EQE of the devices were measured using a solar cell spectral response measurement system (QE-R3011, Enli Technology) at 0 V bias. The dark current noise of the devices was measured using a lock-in amplifier (SR830, Stanford Research System) coupled with a low noise preamplifier (SR570, Stanford Research System). Transient photocurrent curves of the devices were recorded by an oscilloscope with an input impedance of 50Ω when the devices were excited by a pulse laser (337 nm, pulse width ˜3.8 ns).

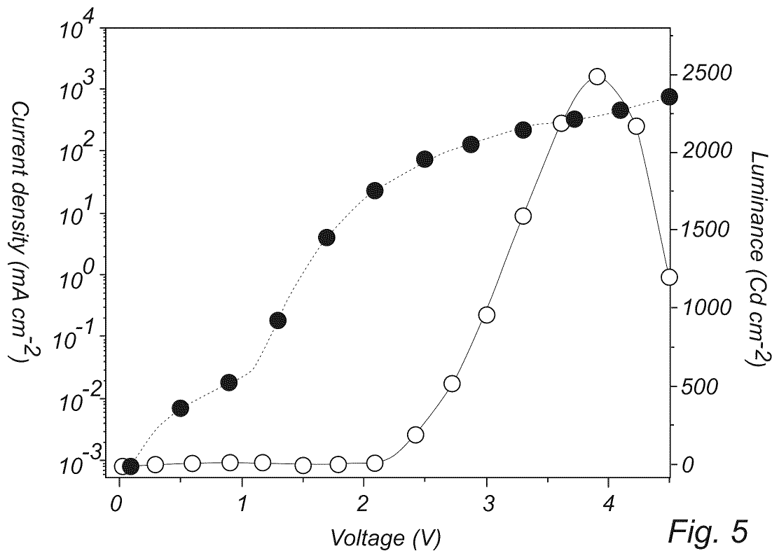

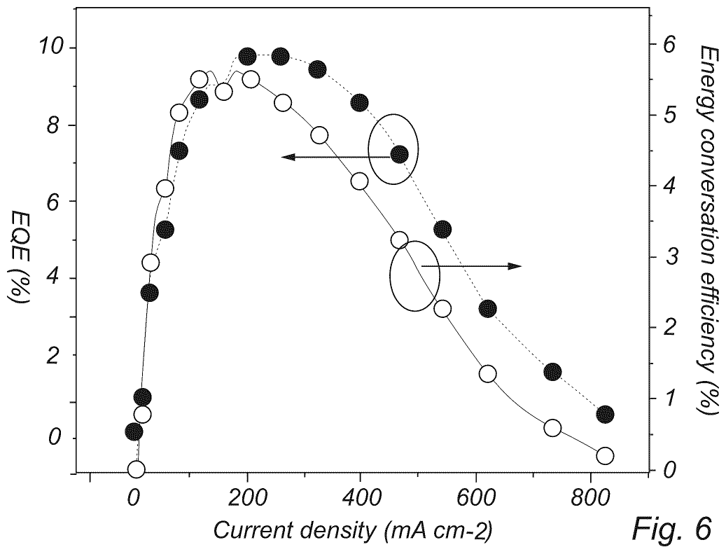

The performance of red LED is shown in in FIGS. 5 and 6. A peak EQE of 9.8% and a luminance of 1600 Cd cm⁻² can be obtained at a drive current density of ˜233 mA cm⁻². The brightness and EQE of the device of the present invention are sufficient for practical application in high brightness display.

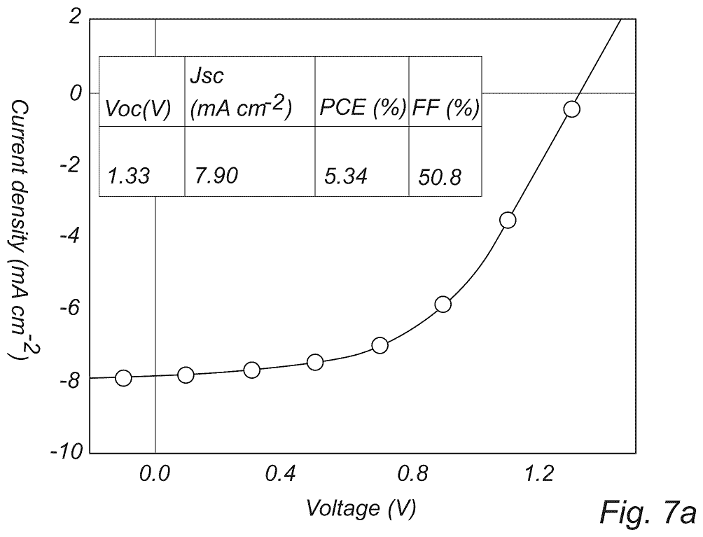

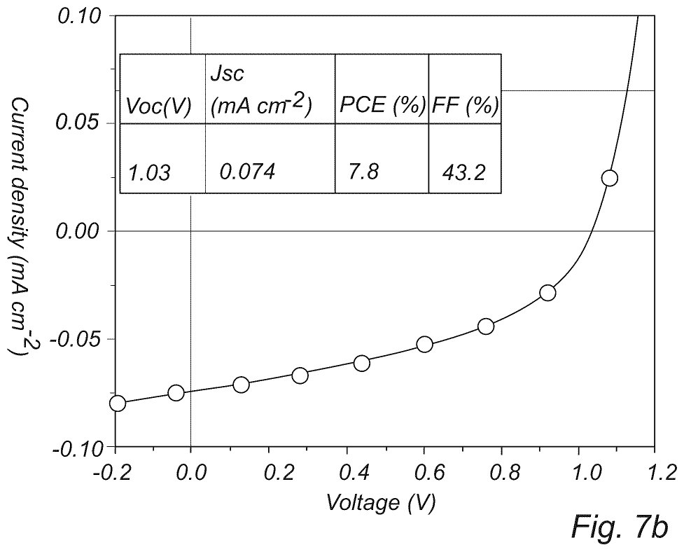

In addition to the potential application as light-emitting pixel in display, our devices show remarkable photo-response and can work as solar cells and photodetectors, as illustrated in FIGS. 7a and 7b. Through optimizing the interface and perovskite layers, a power conversion efficiency of 5.34% at AM1.5G and 7.80% at indoor light (white LED, 4000 K, 1000 lux) was achieved. The higher efficiency at indoor light benefits from the good fitting between the EQE and the emission spectrum of lighting used white LED. The outstanding photo-response of the devices also indicates a potential optical sensing application of the devices.

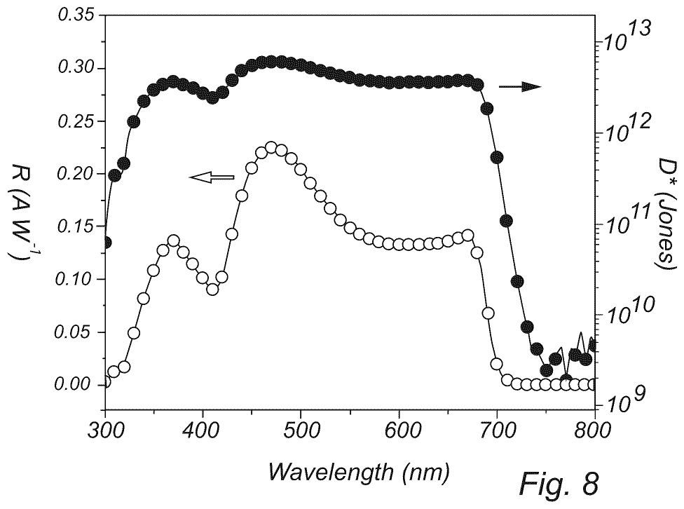

To study the photodetection performance, the dark current noise of the devices was measured. Due to the outstanding defect passivation of the perovskite layer 4, the optimized devices show a peak photo-responsivity of 0.23 A W⁻¹ at 475 nm (FIG. 8), and a remarkable low dark current noise of ˜10 fA Hz^{-0.5}. A low noise equivalent power (NEP) and high peak specific detectivity can be obtained as 44 fW Hz^{-0.5} and 6.08×10¹² Jones, respectively, which are among the most sensitive perovskite photodetectors.

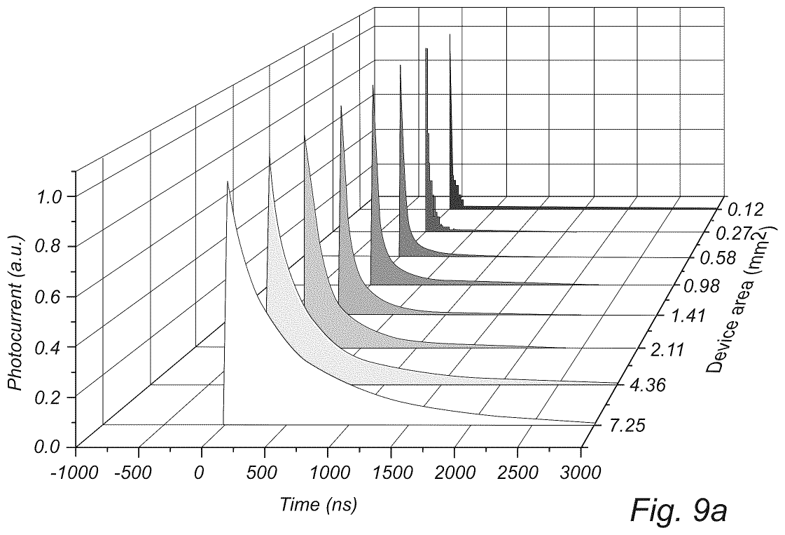

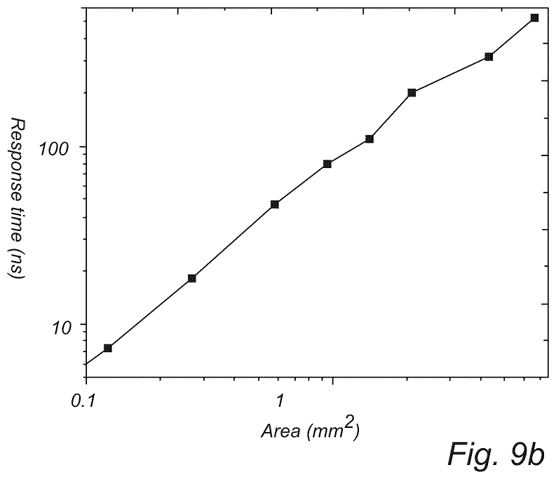

As an optical signal emitting or detection device, the ability of emitting or receiving optical signals is critical. Thus, the response speed of the devices as optical signal emitting and receiving devices was determined. FIG. 9a shows the transient photocurrent (TPC) curves of the devices with different areas when working at photodetector mode. For devices with area above 0.12 mm², the response time are apparently determined by the falling time. Through fitting the TPC curve with a single exponential function, the falling time was obtained as depicted in FIG. 9b, showing that the falling time decrease from 520 ns for 7.25 mm²-area device to 7.5 ns for 0.12 mm²-area device. When the device area further decreases to 0.06 mm², the raising time was comparable to the falling time.

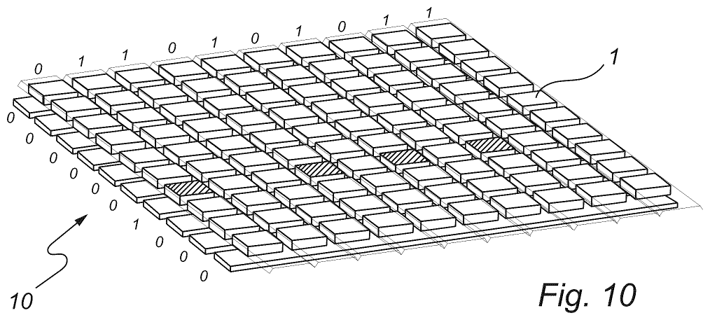

Further, the potential application of the perovskite LED in multifunctional display was demonstrated. The proof-of-concept display device 10 containing 1024 pixels 1 is schematically shown in FIG. 10. The emissive layer and charge transport layers were spin coated on patterned ITO glass, and the Au electrodes were deposited using a patterned mask. Pixels are defined by the overlap of the ITO and Au electrodes. Information is displayed though controlling the on and off state of the pixels 1 using shift registers. The demonstration indicates that the perovskite LEDs are sufficient in brightness and operation speed for a practical small-area passive-matrix display application.

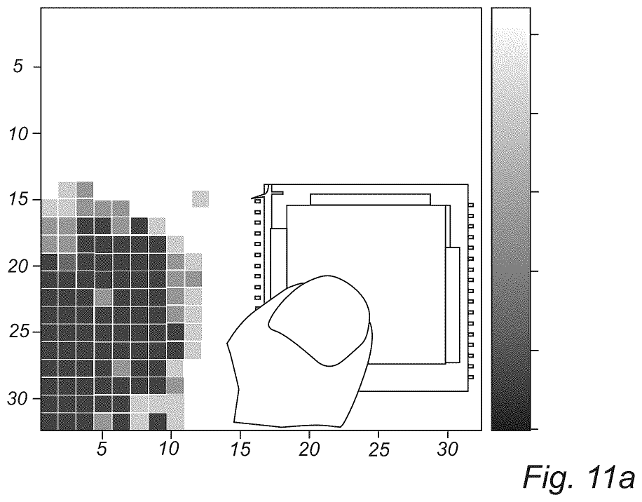

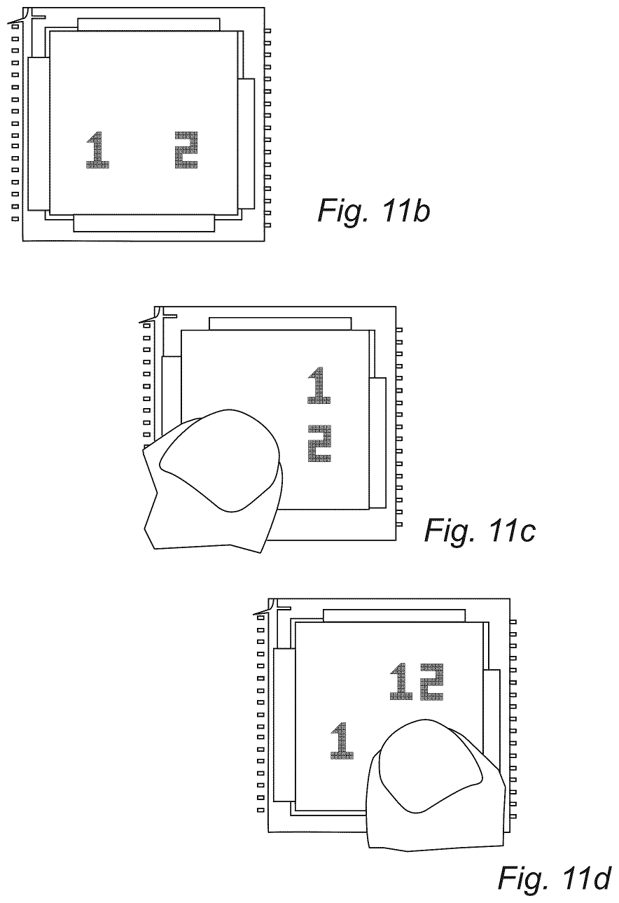

The touch screen function can be practically realized by the proof-of-concept display. The touch position on the display can be sensed by detecting the photocurrent of each pixel. FIG. 11a shows the photocurrent mapping of the display under touching, which clearly shows the touch position. FIGS. 11b-d shows the images of inputting information through the touch screen function of the photo-response display.

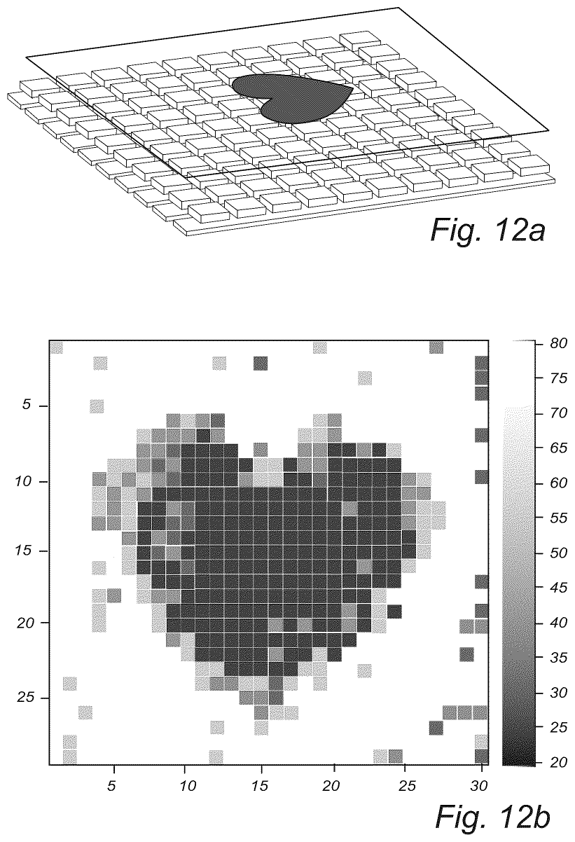

The photo-responsive display pixel array 10 can also be used as imaging sensor. FIG. 12a schematically illustrates the imaging process of the contact surface using a photo-responsive display. The pixel working at photodetector mode receive the light emitted by the nearby pixel working at LED mode and reflected by the surface of the contact object. The imaging function of our display make it promising for the application of screen-based scanner. FIG. 12b shows the image scanned by the proof-of-concept display 10. The full color is supposed to be readily realized based on a full color photo-response display.

Another impressive potential application of the imaging function of the display of the present invention is acting as on-display optical fingerprint sensor. Fingerprint recognition is one of the most welcome security and access control strategies in consumer electronics. Generally, fingerprint only can be read in the specific position where the fingerprint reader was fixed. Multi-point fingerprint recognition solutions have been paid attention due to the attractive new user experience it can produce, such as the encryption and unlocking for different specific apps, and joint signature with fingerprints. Displays based on the devices described herein can read fingerprint at any part of the display, which makes display based on our devices a promising solution for in-screen multi-point fingerprint recognition.

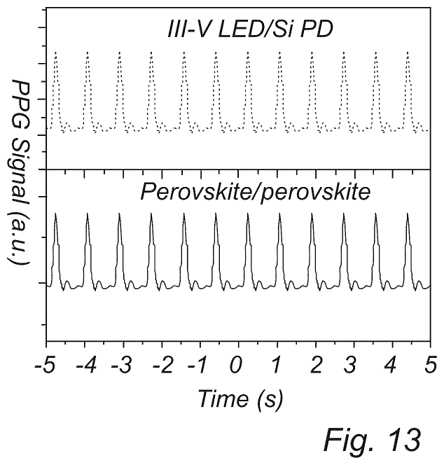

The high brightness of the device of the present invention working in LED mode and high photosensitivity working in detector mode enable using the display for monitoring the photoplethysmography (PPG) and oxyhemoglobin saturation, which would be beneficial not only in health monitoring, but can also improve the security level of fingerprint recognition by monitor the liveness of PPG signal. The inventors show the PPG signal captured by the proof-of-concept display using 10×10 pixels as LED and another 10×10 pixels as detector (FIG. 13). The simultaneous PPG signal captured by a commercial PPG sensor based on III-V LED and Si photodetector is also shown for comparation. The similar PPG signals obtained by the devices of the present invention compared with the commercial one indicates our devices show decent signal/noise ratio when using as PPG sensor.

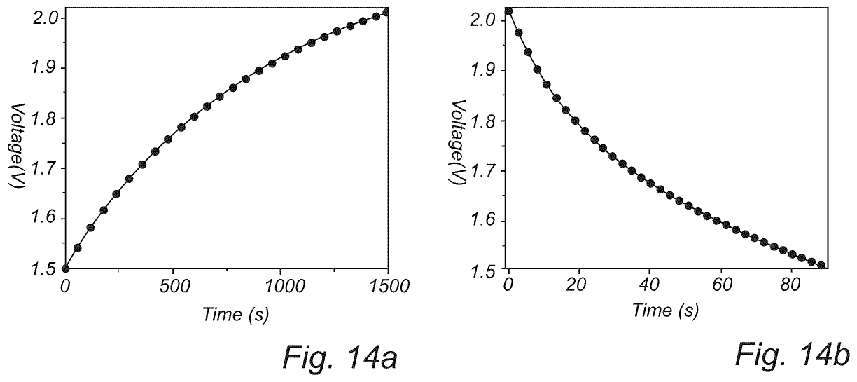

The high power conversion efficiency of the devices described herein in indoor light offers the photovoltaic capability to our display to charge the electronic productor by conversing the light into electricity. FIG. 14a shows the charging curve of a supercapacitor using our devices working as solar cells under AM1.5G sunlight simulator. FIG. 14b shows the discharging curve of the charged supercapacitor when driving the devices working as LEDs.

The inventors have proposed a multi-functional display based on photo-responsive perovskite LEDs as pixels. The multi-functional display has been demonstrated to be simultaneously capable to act as touch screen, ambient light sensing and fingerprint sensing, which are at most case indispensable functions in electronic products. Moreover, the high photo-responsivity of the pixels makes the display screen a platform for man-machine interaction and communication function development. As examples, functions such as screen-based scanner, screen-based data transfer, PPG sensing and charging through screen were demonstrated, using a proof-of-concept devices in the real world.

As mentioned above, through the effective defect passivation and interface engineering, the inventors significantly improved the power conversion efficiency of the red pixel to indoor LED light (4000 K, 1000 lux) with a value of 7.8%, which enables the display to act as a photovoltaic device to charge the equipment. The photo-response speed of the pixel can reach tens of MHz, which makes it is possible to realize data transmission through the displays. These results demonstrate a fascinating advantage of perovskite LED when utilized in display field.

Although the present invention has been described with reference to various embodiments, those skilled in the art will recognize that changes may be made without departing from the scope of the invention. It is intended that the detailed description be regarded as illustrative and that the appended claims including all the equivalents are intended to define the scope of the invention.

What is claimed:

1. A multifunctional optoelectronic device (10) comprising:
at least one photo-responsive perovskite light-emitting diode (LED, 1) arranged to alternatingly operate in emission mode and sensing mode, wherein said at least one perovskite LED (1) comprises a cathode (2), an electron transport layer (ETL, 3) having a lowest unoccupied molecular orbital (LUMO) level and a highest occupied molecular orbital (HOMO) level, a perovskite layer (4) having a conduction band (CB) and a valence band (VB), a hole transport layer (HTL, 5) having a LUMO level and a HOMO level, and an anode (6), wherein said LUMO level of said ETL (3) is lower than said CB bottom of said perovskite layer, and said HOMO level of said HTL (5) is higher than said VB top of said perovskite layer (4);
said multifunctional device (10) further comprising a sensing circuit comprising a sensor arranged to determine the electric current through said at least one perovskite LED (1) and a switch arranged to select between said emission mode and said sensing mode of said perovskite LED (1) as a function of said electric current through said at least one perovskite LED (1).

2. The multifunctional device (10) according to claim 1, wherein said perovskite layer (4) comprises a metal halide perovskite.

3. The multifunctional device (10) according to claim 2, wherein said metal halide perovskite is a metal halide perovskite having a general formula AM^{II}X₃, a double perovskite having general formula A₂M^{I}M^{III}X₆, a layered perovskite having general formula A′AₙMₙX₃ₙ₊₁ or combination thereof.

4. The multifunctional device (10) according to claim 3, wherein A is a small monovalent cation, A′ is a is a large monovalent cation, M^{I} is a monovalent metal cation, M^{II} is a divalent metal cation, M^{III} is a trivalent metal cation, and X is an anion.

5. The multifunctional device (10) according to claim 4, wherein said small monovalent cation is selected from a group consisting of methylammonium (MA⁺), formamidinium (FA⁺), Cs⁺ and combination thereof.

6. The multifunctional device (10) according to claim 4, wherein said large monovalent cation is an aliphatic or aromatic alkylammonium.

7. The multifunctional device (10) according to claim 4, wherein said monovalent metal cation is Ag+, and/or said divalent metal cation is selected from a group consisting of Pb²⁺, Sn²⁺, Ga²⁺, Ge²⁺ and combinations thereof, and/or said trivalent metal cation is selected from a group consisting of Bi³⁺, In³⁺, Sb³⁺ and combinations thereof.

8. The multifunctional device (10) according to claim 4, wherein said anion is a halide anion.

9. The multifunctional device (10) according to claim 8, wherein said anion is a mixture of bromide (Br⁻), iodide (I⁻) and chloride (Cl⁻).

10. The multifunctional device (10) according to any one of the preceding claims, wherein said perovskite layer (4) comprises a passivation agent.

11. The multifunctional device (10) according to claim 10, wherein said passivation agent is 2,2′-(ethylenedioxy)diethylamine (EDEA), 2,2′-(oxybis(ethylenoxy))diethylamine (ODEA), 5-aminovaleric acid (5-AVA), 5-aminovaleric acid hydroiodide (5-AVAI), or 5-aminovaleric acid hydrobromide (5-AVABr) or combination thereof.

12. The multifunctional device (10) according to any one of the preceding claims, wherein said multifunctional device (10) comprises a driving circuit, and wherein said sensing circuit is integrated into said driving circuit.

13. The multifunctional device (10) according to claim 1, wherein the thickness of said ETL (3) and/or said HTL (5) is from 20 nm to 100 nm, and wherein the thickness of said perovskite layer (4) is from 50 nm to 500 nm.

14. The multifunctional device (10) according to claim 1, wherein said ETL (3) is polyethylenimine ethoxylated (PEIE) modified or pure zinc oxide (ZnO), tin oxide (SnO₂) or titanium oxide (TiO₂).

15. The multifunctional device (10) according to claim 1, wherein said HTL (5) is poly(9,9-dioctylfluorene-co-N-(4-sec-butylphenyl)-diphenylamine) (TFB)/molybdenum oxide (MoOₓ).
